(19) United States
(12) Patent Application Publication
(10) Pub. No.: US 2013/0328159 A1
(43) Pub. Date: Dec. 12, 2013

(54) IMPLEMENTING ISOLATED SILICON REGIONS IN SILICON-ON-INSULATOR (SOI) WAFERS USING BONDED-WAFER TECHNIQUE

(71) Applicants: Karl R. Erickson, Rochester, MN (US); Phil C. Paone, Rochester, MN (US); David P. Paulsen, Dodge Center, MN (US); John E. Sheets, II, Zumbrota, MN (US); Gregory J. Uhlmann, Rochester, MN (US); Kelly L. Williams, Rochester, MN (US)

(72) Inventors: Karl R. Erickson, Rochester, MN (US); Phil C. Paone, Rochester, MN (US); David P. Paulsen, Dodge Center, MN (US); John E. Sheets, II, Zumbrota, MN (US); Gregory J. Uhlmann, Rochester, MN (US); Kelly L. Williams, Rochester, MN (US)

(73) Assignee: INTERNATIONAL BUSINESS MACHINES CORPORATION, Armonk, NY (US)

(21) Appl. No.: 13/494,106

(22) Filed: Jun. 12, 2012

(51) Int. Cl. H01L 29/06; H01L 21/762

(52) U.S. Cl. 257/506; 438/455; 257/E29.02; 257/E21.567

(57) ABSTRACT

Methods and structures are provided for implementing independently voltage controlled isolated silicon regions under a buried oxide layer for biasing field effect transistors above the buried oxide layer on Silicon-on-Insulator (SOI) wafers. Using a bonded-wafer technique, a first bulk substrate wafer is bonded with a second wafer providing a buried oxide (BOX) layer under a transistor silicon layer creating an SOI wafer. An independently voltage controlled isolated silicon region is created in the created SOI wafer beneath the BOX layer. The transistor silicon layer is polished to a desired thickness, and normal processing is continued with transistors and desired circuits placed over the isolated silicon region. A contact is formed through the transistor silicon layer and BOX layer to the isolated silicon region for connecting the independently voltage controlled isolated silicon region to a voltage.

### FIELD OF THE INVENTION

The present invention relates generally to the data processing field, and more particularly, relates to methods and structures for implementing independently voltage controlled isolated silicon regions under a buried oxide layer for biasing field effect transistors above the buried oxide layer applying a triple-well technique or deep trench technique to Silicon-on-Insulator (SOI) wafers created using a bonded-wafer technique.

### DESCRIPTION OF THE RELATED ART

It can be useful to provide independently voltage controlled isolated silicon regions particularly for independent backside biasing beneath sensitive circuits on SOI substrates. It can be useful to provide selective isolation or tunable backside biasing which can be used to tweak power and performance characteristics of transistors, circuits or functional macros on SOI chips.

A need exists for an effective mechanism and method of fabricating independently voltage controlled isolated silicon regions under a buried oxide layer for biasing circuits, functional macros, and field effect transistors above the buried oxide layer. It is desirable to provide such effective mechanism and method that eliminates damage to the circuits, functional macros, and field effect transistors resulting from the implant energy required for a conventional implant through the transistor silicon layer and the BOX layer.

### SUMMARY OF THE INVENTION

Principal aspects of the present invention are to provide methods and structures for implementing independently voltage controlled isolated silicon regions under a buried oxide layer for biasing field effect transistors above the buried oxide layer applying a triple-well technique or deep trench technique to Silicon-on-Insulator (SOI) wafers created using a bonded-wafer technique. Other important aspects of the present invention are to provide such methods and structures substantially without negative effects and that overcome many of the disadvantages of prior art arrangements.

In brief, methods and structures are provided for implementing independently voltage controlled isolated silicon regions under a buried oxide layer for biasing field effect transistors above the buried oxide layer on Silicon-on-Insulator (SOI) wafers. Using a bonded-wafer technique, a first bulk substrate wafer is bonded with a second wafer providing a buried oxide (BOX) layer under a transistor silicon layer creating an SOI wafer. An independently voltage controlled isolated silicon region is created in the created SOI wafer beneath the BOX layer. The transistor silicon layer is polished to a desired thickness, and normal processing is continued with transistors and desired circuits placed over the isolated silicon region. A contact is formed through the transistor silicon layer and BOX layer to the isolated silicon region for connecting the independently voltage controlled isolated silicon region to a voltage.

In accordance with features of the invention, the independently voltage controlled isolated silicon region is created by forming triple-well regions on the first bulk substrate wafer, forming an oxide layer over the first bulk substrate wafer in contact engagement with the triple-well regions and then the first substrate wafer is bonded with the second wafer providing a buried oxide (BOX) layer below the second wafer substrate and creating the independently voltage controlled isolated silicon region in the created SOI wafer in a well region beneath the BOX layer.

In accordance with features of the invention, the independently voltage controlled isolated silicon region is created by implanting a buried dopant implant layer extending throughout the entire first bulk substrate wafer, forming an oxide layer over the first bulk substrate wafer contacting a silicon layer formed above the implanted layer on the first bulk substrate wafer and then the first substrate wafer is bonded with the second wafer providing a buried oxide (BOX) layer below the second wafer substrate transistor silicon layer and contacting a silicon layer formed above the implanted layer, and deep trenches are etched and filled to define isolation sides of the independently voltage controlled isolated silicon region.

In accordance with features of the invention, a contact is formed to each independently voltage controlled isolated silicon region defined by etched and filled deep trench isolation in the created SOI wafer.

In accordance with features of the invention, creating the independently voltage controlled isolated silicon region using the bonded-wafer technique eliminates all damage to the top transistor silicon layer and the BOX layer, otherwise resulting from the implant energy required for a conventional implant through the transistor silicon layer and the BOX layer.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a flow chart illustrating exemplary processing steps for fabricating an independently voltage controlled isolated silicon region under a buried oxide layer for biasing field effect transistors, functional macros, and circuits above the buried oxide layer applying a triple-well technique to Silicon-on-Insulator (SOI) wafers created using a bonded-wafer technique in accordance with a preferred embodiment;

FIGS. 2A, 2B, 2C, 2D, and 2e are side views not to scale illustrating key process steps for implementing independently voltage controlled isolated silicon regions under a buried oxide layer for biasing field effect transistors, functional macros, and circuits above the buried oxide layer applying a triple-well technique to Silicon-on-Insulator (SOI) wafers created using a bonded-wafer technique in accordance with a preferred embodiment;

FIG. 3 is a flow chart illustrating alternative exemplary processing steps for fabricating an independently voltage controlled isolated silicon region under a buried oxide layer for biasing field effect transistors, functional macros, and circuits above the buried oxide layer applying a deep trench technique to Silicon-on-Insulator (SOI) wafers created using a bonded-wafer technique in accordance with a preferred embodiment; and

FIGS. 4A, 4B, 4C, 4D, 4E, and 4F are side views not to scale illustrating key process steps for implementing independently voltage controlled isolated silicon regions under a buried oxide layer for biasing field effect transistors, functional macros, and circuits above the buried oxide layer applying a deep trench processing technique to Silicon-on-Insulator (SOI) wafers created using a bonded-wafer technique in accordance with a preferred embodiment.

### DETAILED DESCRIPTION OF THE PREFERRED EMBODIMENTS

In the following detailed description of embodiments of the invention, reference is made to the accompanying drawings, which illustrate example embodiments by which the invention may be practiced. It is to be understood that other embodiments may be utilized and structural changes may be made without departing from the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In accordance with features of the invention, methods and structures are provided for implementing independently voltage controlled isolated silicon regions under a buried oxide layer for biasing field effect transistors above the buried oxide layer on Silicon-on-Insulator (SOI) wafers. The SOI wafers are created using a bonded-wafer technique in accordance with preferred embodiments.

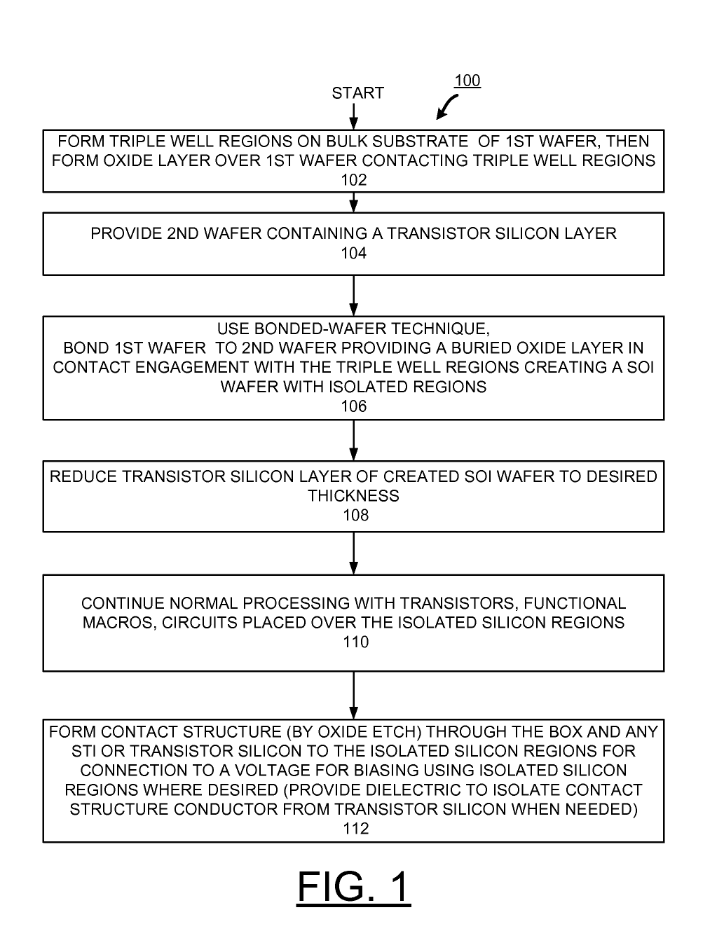

Referring now to FIG. 1, example processing steps generally designated by the reference character 100 are shown illustrating exemplary processing steps for fabricating independently voltage controlled isolated silicon regions under a buried oxide layer for biasing field effect transistors, functional macros, and circuits above the buried oxide layer applying a triple-well technique to Silicon-on-Insulator (SOI) wafers created using a bonded-wafer technique in accordance with preferred embodiments.

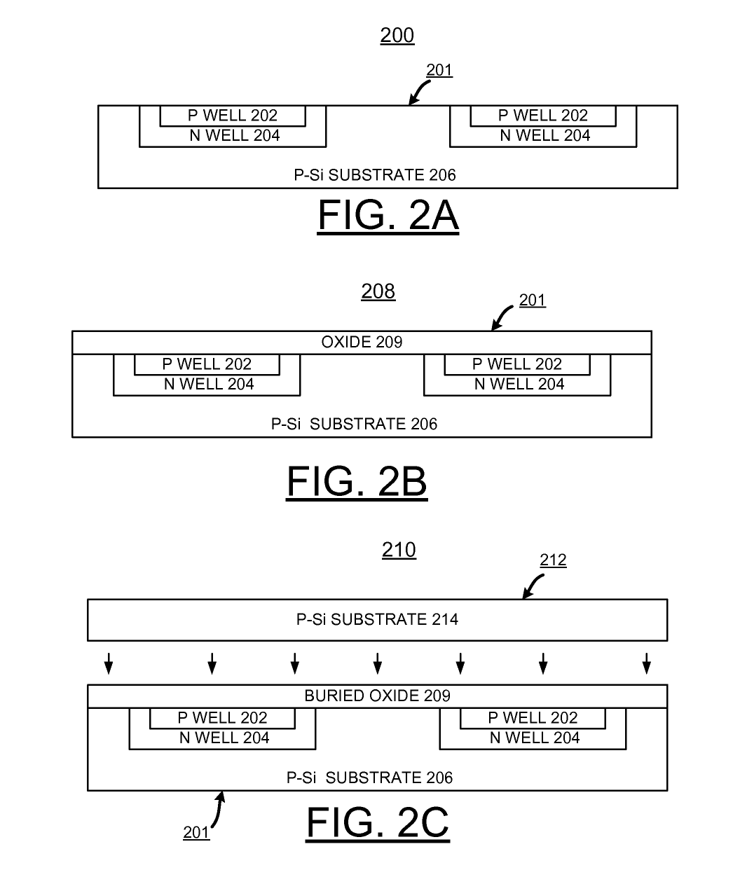

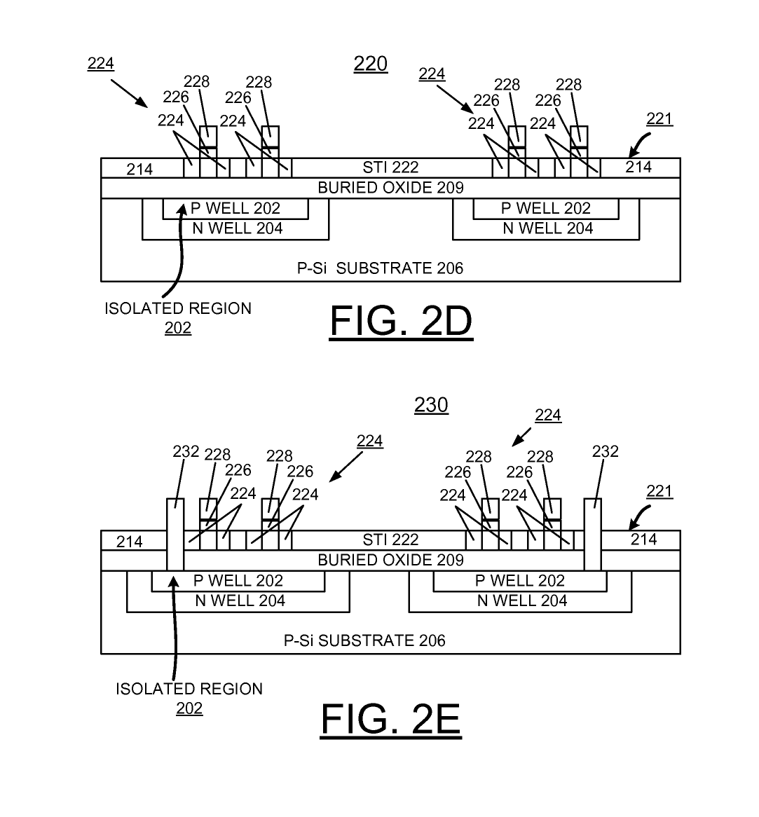

Referring also to FIGS. 2A, 2B, 2C, 2D, and 2E, side views are schematically shown not to scale illustrating key process steps for implementing an independently voltage controlled isolated silicon region under a buried oxide layer for biasing field effect transistors, functional macros, and circuits above the buried oxide layer applying a triple-well technique to Silicon-on-Insulator (SOI) wafers created using a bonded-wafer technique in accordance with preferred embodiments. FIGS. 1, 2A, 2B, 2C, 2D, and 2E are shown in simplified form sufficient for understanding the invention.

As indicated at a block 102 in FIG. 1, triple well regions are formed on a first bulk substrate. An initial processing step generally designated by the reference character 200 of a first bulk wafer 201 is illustrated in FIG. 2A. As shown, the initial processing step 200 includes patterning triple well regions including P well regions 202 formed within N well regions 204 in a P-Silicon substrate 206 of the first wafer 201. While a substrate that is P-doped silicon is shown for first bulk wafer 201, an oppositely doped substrate or N—Si substrate could be used with reversed P well and N well regions.

As shown in FIG. 2B, a next processing step generally designated by the reference character 208 is illustrated and as indicated at a block 102 in FIG. 1, an oxide layer 209 is formed over the first bulk wafer 201 contacting the triple well regions including the P well regions 202 formed within N well regions 204 in a P-Silicon substrate 206.

As shown in FIG. 2C, a next processing step generally designated by the reference character 210 is illustrated and as indicated at a block 104 in FIG. 1, a second wafer 212 is provided containing a transistor silicon layer 214. When the second wafer 212 is bonded to the first wafer 201 a buried oxide (BOX) layer 209 is created under the P-Silicon substrate or transistor silicon layer 214.

Using a bond-wafer technique, the first wafer 201 is bonded to the second wafer 212 creating the buried oxide 209 with the buried oxide (BOX) layer 209 provided in contact engagement with the triple-well regions 202, 204, 206 as indicated at a block 106 in FIG. 1. The processing step 210 illustrates this bonding step using the bond-wafer technique to create a SOI wafer with the P-well regions 202 defining isolated silicon regions 202 in the created SOI wafer 221 as shown in FIG. 2D.

In FIG. 2D a next processing step generally designated by the reference character 220 is illustrated. The transistor silicon layer 214 of the created SOI wafer 221 is polished or ground to a desired thickness as indicated at a block 108 in FIG. 1 and shown in FIG. 2D. Normal processing is continued with transistors, functional macros, desired circuits placed over the isolated silicon regions 202 as indicated at a block 110 in FIG. 1.

Shallow trench isolation (STI) 222 is formed in the transistor silicon layer 214 and a respective circuit or field effect transistor (FET) 224 is formed over the isolated silicon regions 202 defined by the P-well regions 202 as indicated by a plurality of example circuit regions 224, 226, and 228.

In FIG. 2E a next processing step generally designated by the reference character 230 is illustrated. As indicated at a block 112 in FIG. 1 and shown in FIG. 2E, contact structures 232 containing a conductive material or conductor are formed, for example, by oxide etch through the BOX layer 209 and any STI 222 or the transistor silicon layer 214 to the isolated silicon regions 202 where contacts are needed. The conductive material forming contact structures 232 may be tungsten, doped polysilicon, or other suitable conducting material. When required a dielectric material spacer isolates the contact structure conductor from the P-silicon transistor silicon layer 214. The dielectric material may be silicon dioxide SiO2, hafnium dioxide HfO2, or a low-K dielectric, depending on a particular process selected for fabricating the created SOI wafer or SOI chip 221.

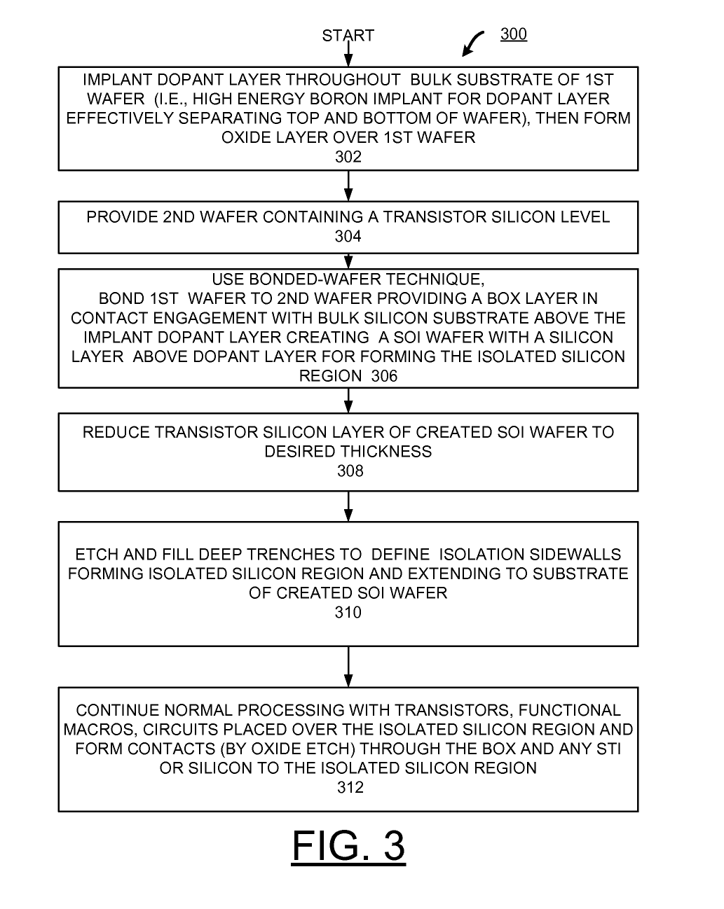

Referring now to FIG. 3, there are shown exemplary processing steps generally designated by the reference character 300 for fabricating an independently voltage controlled isolated silicon region under a buried oxide layer for biasing field effect transistors, functional macros, and circuits above the buried oxide layer applying a deep trench processing technique to Silicon-on-Insulator (SOI) wafers created using a bonded-wafer technique in accordance with preferred embodiments.

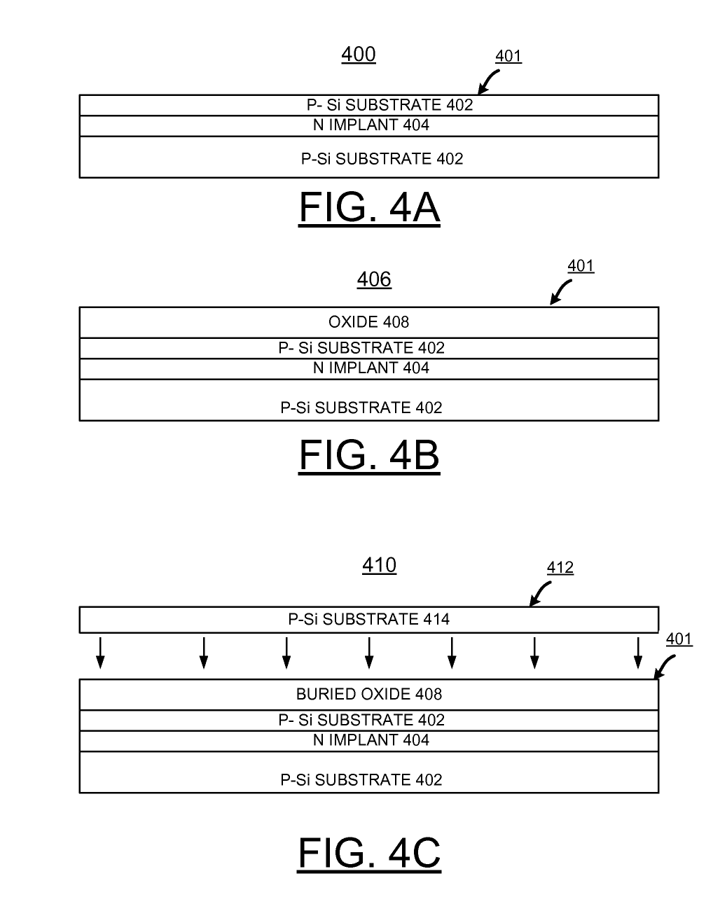

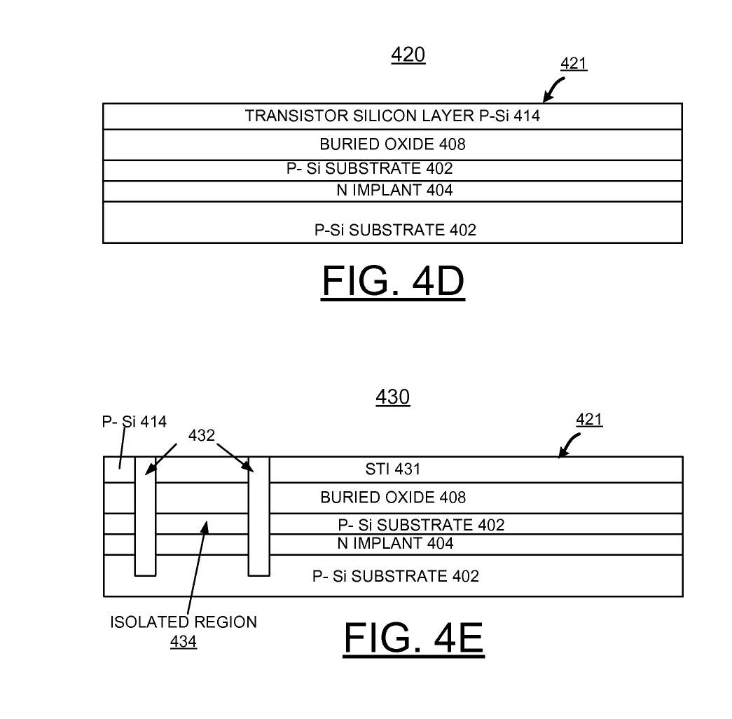

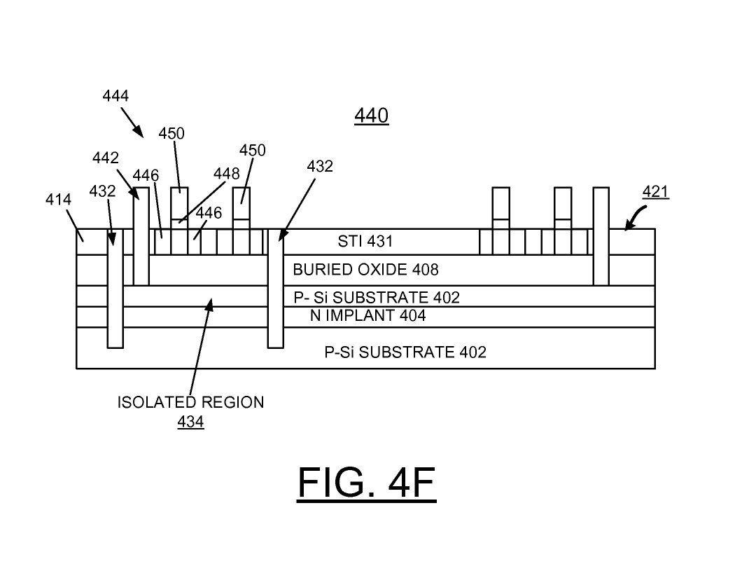

Referring also to FIGS. 4A, 4B, 4C, 4D, 4E and 4F, side views are schematically shown not to scale illustrating alternative key process steps for implementing an isolated silicon region under a buried oxide layer for biasing field effect transistors, functional macros, and circuits above the buried oxide layer applying a deep trench processing technique to Silicon-on-Insulator (SOI) wafers created using a bonded-wafer technique in accordance with preferred embodiments.

An initial processing step generally designated by the reference character 400 of a first bulk wafer 401 including a P-Silicon substrate 402 is illustrated in FIG. 4A. As indicated at a block 302 in FIG. 3 and shown in FIG. 4A, an N implant or dopant layer 404 is implanted throughout the entire wafer 401 effectively separating the top and bottom of the first bulk substrate 402. For example, a high energy boron implant creates N implant layer 404, such as 4 MeV boron implant will create the N implant layer 404.

As shown in FIG. 4B in a next processing step 406 and as indicated at a block 302 in FIG. 3, an oxide layer 408 is formed over the first wafer 401 in contact engagement with the P-Silicon substrate 402 above the N implant layer 404.

In FIG. 4C, there is shown in a next processing step generally designated by the reference character 410 and indicated at a block 304 in FIG. 3, a second wafer 412 is provided containing a P—Si substrate layer 414. The second wafer 412 includes the P-Silicon substrate 414 to be used as transistor silicon substrate layer 414.

Using a bond-wafer technique, the first wafer 401 is bonded to the second wafer 412 providing a buried oxide (BOX) layer 408 in contact engagement with the P-Silicon substrate 402 above the N implant layer 404 as indicated at a block 306 in FIG. 3. The processing step 410 creates a SOI wafer 421 as depicted in FIG. 4D with P-Silicon substrate 402 above the N dopant layer 404 for defining an independently voltage controlled isolated silicon region 434 as shown in FIG. 4E in the created SOI wafer 421.

As shown in FIG. 4D in a next processing step 420 and as indicated at a block 308 in FIG. 3, the transistor silicon layer 414 of the created SOI wafer 421 is polished or ground to a desired thickness.

In FIG. 4E a next processing step generally designated by the reference character 430 is illustrated. Shallow trench isolation (STI) 431 is formed in the transistor silicon layer P—Si 414. As indicated at a block 310 in FIG. 3 and shown in FIG. 4E, deep trenches are etched and filled to define isolation sidewalls 432 or deep trench (DT) isolation 432 defining an isolated silicon region 434 in the P—Si layer 402 above the N implant layer 404. The DT isolation 432 extends at least down to, and advantageously below, N implant layer 404. Deep trench isolation 432 may be created using a conventional process such as used to create eDRAM capacitors, but is elongated to form sides of the independently voltage controlled isolated silicon region 434.

In FIG. 4F a next processing step generally designated by the reference character 440 is illustrated. As indicated at a block 312 in FIG. 3 and shown in FIG. 4F, contact structures 442 containing a conductive material or conductor are formed, for example, by oxide etch through the BOX layer 408 and any STI 431 or the transistor silicon layer 414 to the isolated silicon region 434. The conductive material forming contact structures 442 may be tungsten, doped polysilicon, or other suitable conducting material. A dielectric material spacer isolates the contact structure conductor from P-silicon transistor silicon layer 414 when required, which may be silicon dioxide SiO2, hafnium dioxide HfO2, or a low-K dielectric, depending on a particular process selected for fabricating the created SOI wafer or SOI chip 421. A circuit or field effect transistor (FET) 444 is formed over the isolated silicon regions 434 as indicated by a plurality of example circuit regions 446, 448, and 450.

While the present invention has been described with reference to the details of the embodiments of the invention shown in the drawing, these details are not intended to limit the scope of the invention as claimed in the appended claims.

1. A structure for implementing independently voltage controlled isolated silicon region under a buried oxide layer for biasing field effect transistors above the buried oxide layer on Silicon-on-Insulator (SOI) wafers comprising:
a first bulk substrate wafer including an oxide layer;
a second wafer containing a transistor silicon layer being bonded to said first bulk substrate wafer providing a buried oxide (BOX) layer under said transistor silicon layer creating an SOI wafer;
an independently voltage controlled isolated silicon region being created in said created SOI wafer beneath said BOX layer;
said transistor silicon layer being processed for forming field effect transistors and predefined circuits over said independently voltage controlled isolated silicon region; and
a contract structure including a conducting material formed through said transistor silicon layer and said BOX layer to said isolated silicon region for connecting the independently voltage controlled isolated silicon region to a voltage.

2. The structure as recited in claim 1 wherein said first bulk substrate wafer includes triple-well regions, and said oxide layer extending over the first bulk substrate wafer in contact engagement with the triple-well regions, said first substrate wafer is bonded with said second wafer providing said buried oxide (BOX) layer below said second wafer transistor silicon layer, and creating said independently voltage controlled isolated silicon region being created in said created SOI wafer beneath said BOX layer.

3. The structure as recited in claim 1 wherein said first bulk substrate wafer includes a buried dopant layer extending throughout said first bulk substrate wafer; and said oxide layer extending over the first bulk substrate wafer contacting a silicon layer formed above said buried dopant layer on the first bulk substrate wafer, said buried dopant layer having opposite doping to a substrate doping of said created SOI wafer, and said first substrate wafer is bonded with said second wafer providing said buried oxide (BOX) layer below said second wafer transistor silicon layer and in contact engagement with a silicon layer formed above said dopant layer.

4. The structure as recited in claim 3 includes etched and filled deep trenches defining deep trench electrical isolation sides of said isolated silicon region.

5. The structure as recited in claim 1 wherein said etched and filled deep trenches extend through said created SOI wafer to said first bulk substrate below said buried dopant layer.

6. The structure as recited in claim 1 wherein said contact structure extends through a shallow trench isolation region in said transistor silicon layer.

7. The structure as recited in claim 1 wherein said conducting material of said contact structure includes a selected material from a group including a doped polysilicon, copper, aluminum, and tungsten.

8. The structure as recited in claim 1 wherein said contact structure includes a dielectric material isolating said conducting material of said contact structure from said transistor silicon layer.

9. The structure as recited in claim 8 wherein said dielectric material includes a selected material from a group including hafnium dioxide (HfO2) and silicon dioxide (SiO2).

10. A method for implementing independently voltage controlled isolated silicon regions under a buried oxide layer for biasing field effect transistors above the buried oxide layer on Silicon-on-Insulator (SOI) wafers comprising:
providing a first bulk substrate wafer including an oxide layer and a second bulk substrate wafer containing a transistor silicon layer and forming triple-well regions in said first bulk substrate wafer, and forming said oxide layer extending over the first bulk substrate wafer in contact engagement with the triple-well regions;
using a bonded-wafer technique, bonding said first bulk substrate wafer with said second wafer providing a buried oxide (BOX) layer under a said transistor silicon layer for creating an SOI wafer and forming a top surface of an independently voltage controlled isolated silicon region with said BOX layer including an said independently voltage controlled isolated silicon region beneath said BOX layer;
processing said transistor silicon layer for placing transistors and desired circuits placed over said isolated silicon region; and
forming a contact structure through said transistor silicon layer and said BOX layer to said independently voltage controlled isolated silicon region for connecting the independently voltage controlled isolated silicon region to a voltage.

11. (canceled)

12. The method as recited in claim 10 wherein providing said first bulk substrate wafer includes providing a buried dopant layer extending throughout said first bulk substrate wafer; and forming said oxide layer extending over the first bulk substrate wafer contacting a silicon layer formed above said buried dopant layer on the first bulk substrate wafer, said buried dopant layer having opposite doping to a substrate doping of said created SOI wafer, and wherein bonding said first bulk substrate wafer with said second wafer providing said buried oxide (BOX) layer under said transistor silicon layer for creating an SOI wafer includes forming a top surface of said independently voltage controlled isolated silicon region with said BOX layer.

13. The method as recited in claim 12 includes etching and filling deep trenches defining deep trench (DT) isolation sides of said independently voltage controlled isolated silicon region.

14. The method as recited in claim 13 wherein said etched and filled deep trenches extend through said created SOI wafer to said first bulk substrate.

15. The method as recited in claim 10 wherein forming said contact structure through said transistor silicon layer and said BOX layer to said independently voltage controlled isolated silicon region includes etching through a shallow trench isolation region in said transistor silicon layer and said BOX layer to said isolated silicon region forming said contact structure.

16. The method as recited in claim 10 wherein forming said contact structure includes providing a conducting material selected from a group including a doped polysilicon, copper, aluminum, and tungsten.

17. The method as recited in claim 16 wherein forming said contact structure includes providing a dielectric material isolating said conducting material of said contact structure from said transistor silicon layer.

18. The method as recited in claim 17 wherein said dielectric material includes a selected material from a group including hafnium dioxide (HfO2) and silicon dioxide (SiO2).
